(19) United States
(12) Patent Application Publication
(10) Pub. No.: US 2002/0094040 A1
(43) Pub. Date: Jul. 18, 2002

(54) Apparatus for and method of receiving broadcasting signals

(76) Inventor: Kazuhiro Oyagi, Kanagawa (JP)

Correspondence Address: COOPER & DUNHAM LLP, 1185 Avenue of the Americas, New York, NY, 10036, US

(21) Appl. No.: 09/951,255

(22) Filed: Sep. 13, 2001

(30) Foreign Application Priority Data
Sep. 14, 2000 (JP) P2000-279125

(51) Int. Cl. H03D 1/00; H04L 27/06

(52) U.S. Cl. 375/340

(57) ABSTRACT

An apparatus for receiving broadcasting signals, which comprises a signal selecting and receiving portion for selecting one of ensembles to receive, a channel decoder for obtaining program information data and control information data based on the selected ensemble received by the signal selecting and receiving portion, and a control unit operative to detect a condition in which the selected ensemble has not been appropriately received by the signal selecting and receiving portion for more than a predetermined period and, when the condition is detected, to perform a control operation in such a manner as to cause the signal selecting and receiving portion to select another ensemble to receive in accordance with indication by the control information data in the case where the control information data obtained based on the selected ensemble indicate the existence of some other ensemble which is to be received in place of the selected ensemble, and to cause said signal selecting and receiving portion to change a receiving frequency successively so as to detect receivable ensembles one by one and to store in a memory portion control information data obtained from the channel decoder based on each receivable ensemble detected by said signal selecting and receiving portion in the case where the control information data obtained based on the selected ensemble do not indicate the existence of any ensemble which is to be received in place of the selected ensemble.

### BACKGROUND OF THE INVENTION

1. Field of the Invention

The present invention relates generally to an apparatus for and a method of receiving broadcasting signals, and more particularly, to such an apparatus for and a method of receiving broadcasting signals that functions to receive a digital audio broadcasting signal for obtaining a reproduced audio signal based on the received digital audio broadcasting signal and further is able to select automatically a receivable digital audio broadcasting signal as occasion demands.

2. Description of the Prior Art

Although an analog audio broadcasting system which includes an amplitude-modulated (AM) audio broadcasting system in which audio signals are transmitted in the form of an AM audio information signal and a frequency-modulated (FM) audio broadcasting system in which audio signals are transmitted in the form of a FM audio information signal, has been put to practical use for a long time in the field of audio broadcasting, there has been recently proposed to introduce a digital audio broadcasting system in which audio signals are transmitted in the form of a digital audio information signal for the purpose of improving quality of audio information transmitted or received in the system. Especially, in the European Continental, the digital audio broadcasting system called “DAB” has been already put to practical use in some countries.

The digital audio information signal transmitted from a broadcasting station under the digital audio broadcasting system is called a digital audio broadcasting signal. The digital audio broadcasting signal carries not only audio information data representing digital audio signals but also service information data representing service information, such as weather forecast, traffic information and so on, and further carries control information data which are necessitated for reproducing the digital audio signals based on the audio information data and the service information based on the service information data on the receiving side. For the digital audio broadcasting signal, a plurality of pairs of the audio information data and the service information data are usually provided for forming various kinds of program information data representing program information of different kinds.

A digital audio broadcasting signal having a single transmission frequency for carrying the various kinds of program information data representing the audio information data and the service information data, together with the control information data, is called “ensemble”. In the explanation mentioned below, the term of “ensemble” may be often used for representing the digital audio broadcasting signal.

The audio information data and the service information data are transmitted in the form of a series of unit segments each having a time duration of, for example, 24 ms and constituting a logical frame. The logical frame for the audio information data is formed into an audio frame. In the audio frame, audio data representing program information are contained and program associated data (PAD) relative to the program information represented by the audio data are also contained to be successive to the audio data. The program associated data are provided to represent information relative to contents of the related program information. For example, in the case where the related program information is information representing music, the program associated data represent in the form of character information the name of a composer of the music, the name of the music, the title of a recording medium on which the music is recorded and so on.

The digital audio broadcasting signal transmitted under the digital audio broadcasting system as mentioned above, namely, the ensemble is received usually by a digital audio broadcasting signal receiver which is an apparatus provided for exclusive use to receive digital audio broadcasting signals. In the digital audio broadcasting signal receiver, an ensemble transmitted from a certain digital audio broadcasting station is selected to be received by a signal selecting and receiving portion. The received ensemble is subjected to demodulation, program selection and decoding processing in a channel decoding portion. The output of the channel decoding portion is subjected to program extraction by a program extracting portion so that service information data and audio information data are obtained. Then, the audio information data obtained from the program extracting portion are subjected to decoding processing by a source decoding portion so that audio data forming a digital audio signal are reproduced and program associated data are obtained, and service information data obtained from the program extracting portion are subjected to decoding processing by a decoding portion for the service information data so that service information is reproduced. A reproduced audio signal is obtained based on the audio data obtained from the source decoding portion to form the digital audio signal.

The ensemble thus received by the digital audio broadcasting signal receiver is classified to one of first and second types. The ensemble of the first type is transmitted under a local broadcasting with its service area, in which the ensemble can be appropriately received by the digital audio broadcasting signal receiver, limited to be relatively narrow and the ensemble of the second type is transmitted under a large area broadcasting with its service area extends to be relatively broad. Under the local broadcasting, a plurality of service areas in each of which a selected ensemble can be appropriately received by the digital audio broadcasting signal receiver is provided with overlapping partially or without overlapping each other.

Therefore, if the ensemble transmitted under the large area broadcasting is intended to be received by the digital audio broadcasting signal receiver which is installed in a vehicle to move therewith, it is possible to continue reproduction of program information based on a selected program information data over a relatively broad moving range of the vehicle without changing a receiving frequency set on the digital audio broadcasting signal receiver for receiving selectively the ensemble. On the other hand, if the ensemble transmitted under the local broadcasting is intended to be received by the digital audio broadcasting signal receiver which is installed in a vehicle to move with the vehicle, it is required to switch the receiving frequency set on the digital audio broadcasting signal receiver for receiving selectively the ensemble. On the other hand, if the ensemble transmitted under the local broadcasting is intended to be received by the digital audio broadcasting signal receiver which is installed in a vehicle to move with the vehicle, it is required to changing the receiving frequency set on the digital audio broadcasting signal receiver for receiving selectively the ensemble at every movement of the vehicle from one of the service areas to the next service area.

Under such a situation, as to some ensembles, the control information data are provided to represent information related to other ensembles and program information data carried thereby, namely, service link information. The service link information represents, for example, one or more other ensembles each carrying program information data corresponding to the program information data carried by the ensemble carrying the service link information in question.

Accordingly, when the ensemble, which is transmitted under the local broadcasting to carry the program information data and the control information data representing the service link information, is received by the digital audio broadcasting signal receiver which is installed in the vehicle to move therewith, it is possible for the digital audio broadcasting signal receiver which is receiving the ensemble to detect another ensemble carrying program information data corresponding to the program information data carried by the ensemble having been received on the strength of the service link information and to change automatically the receiving frequency set on the digital audio broadcasting signal receiver to another receiving frequency to receive the detected ensemble at the time of the movement of the vehicle from one of the service areas to the next service area.

However, when the ensemble which is transmitted under the local broadcasting is received by the digital audio broadcasting signal receiver which is installed in the vehicle to move therewith and the received ensemble is not accompanied with the control information data representing the service link information, it is impossible for the digital audio broadcasting signal receiver to change automatically the receiving frequency set on the digital audio broadcasting signal receiver to another receiving frequency to receive another ensemble carrying program information data corresponding to the program information data carried by the ensemble having been received at the time of the movement of the vehicle from one of the service areas to the next service area. Consequently, in order to receive, by the digital audio broadcasting signal receiver, a new ensemble carrying program information data corresponding to the program information data carried by the ensemble having been previously received to reproduce the program information data, it is necessary for a user of the digital audio broadcasting signal receiver to have an operation for changing the receiving frequency set on the digital audio broadcasting signal receiver repeatedly to receive receivable ensembles successively and to detect from the ensembles newly received the new ensemble carrying the program information data corresponding to the program information data carried by the ensemble having been previously received.

Such an operation for changing the receiving frequency set on the digital audio broadcasting signal receiver repeatedly is troublesome and annoying to the user of the digital audio broadcasting signal receiver and the user feels inconvenience. Further, if the user of the digital audio broadcasting signal receiver is a driver of the vehicle in which the digital audio broadcasting signal receiver is installed, it is feared that the driving of the vehicle is disturbed by the operation for changing the receiving frequency set on the digital audio broadcasting signal receiver repeatedly.

### OBJECTS AND SUMMARY OF THE INVENTION

Accordingly, it is an object of the present invention to provide an apparatus for or a method of receiving broadcasting signals, by which an ensemble (a digital audio broadcasting signal) is received and at least one of reproduced audio information and reproduced service information is obtained based on the received ensemble, and which avoids the aforementioned disadvantages encountered with the prior art.

Another object of the present invention is to provide an apparatus for or a method of receiving broadcasting signals, by which an ensemble (a digital audio broadcasting signal) is received and at least one of reproduced audio information and reproduced service information is obtained based on the received ensemble, and in which when an ensemble having been received falls into a condition unable to be received, such a condition that a new ensemble from which reproduced audio information or reproduced service information corresponding to the reproduced audio information or the reproduced service information having been obtained is successively obtained is received can be easily established.

A further object of the present invention is to provide an apparatus for or a method of receiving broadcasting signals, by which an ensemble (a digital audio broadcasting signal) is received and at least one of reproduced audio information and reproduced service information is obtained based on the received ensemble, and in which when an ensemble having been received falls into a condition unable to be received, a new ensemble from which reproduced audio information or reproduced service information corresponding to the reproduced audio information or the reproduced service information having been obtained is successively obtained can be received without an operation for changing a receiving frequency repeatedly by a user.

According to the present invention, there is provided an apparatus for receiving broadcasting signals, which comprises a signal selecting and receiving portion for selecting one of ensembles to receive, a first decoding portion for obtaining program information data and control information data based on the selected ensemble received by the signal selecting and receiving portion, a program extracting portion for extracting audio program data from the program information data obtained from the first decoding portion, a second decoding portion for decoding the audio program data obtained from the program extracting portion to obtain a digital audio signal, a sound reproducing portion for reproducing sound based on the digital audio signal obtained from the second decoding portion, and a control unit to which the control information data obtained from the first decoding portion are supplied, wherein the control unit is operative to detect a condition in which the selected ensemble has not been appropriately received by the signal selecting and receiving portion for more than a predetermined period and, when the condition is detected, to perform a control operation in such a manner as to cause the signal selecting and receiving portion to select another ensemble to receive in accordance with an indication by the control information data in the case where the control information data obtained based on the selected ensemble indicate the existence of some other ensemble which is to be received in place of the selected ensemble, and to cause the signal selecting and receiving portion to change a receiving frequency successively within a predetermined frequency range so as to detect receivable ensembles one by one and to store in a memory portion control information data obtained from the first decoding portion based on each receivable ensemble detected by the signal selecting and receiving portion in the case where the control information data obtained based on the selected ensemble do not indicate the existence of any ensemble which is to be received in place of the selected ensemble.

In the apparatus for receiving broadcasting signals thus constituted in accordance with the present invention, under a situation in which the signal selecting and receiving portion is caused to select a certain ensemble to receive, when the selected ensemble has not been appropriately received by the signal selecting and receiving portion for more than the predetermined period, the control unit to which the control information data obtained from the first decoding portion are supplied performs the control operation as follows. If the control information data obtained based on the selected ensemble indicate the existence of some other ensemble which is to be received in place of the selected ensemble, the control unit controls the signal selecting and receiving portion to select another ensemble to receive in accordance with the indication by the control information data. To the contrary, if the control information data obtained based on the selected ensemble do not indicate the existence of some other ensemble which is to be received in place of the selected ensemble, the control unit controls the signal selecting and receiving portion to change the receiving frequency successively within the predetermined frequency range so as to detect the receivable ensembles one by one and stores in the memory portion the control information data obtained from the first decoding portion based on each receivable ensemble detected by the signal selecting and receiving portion.

Therefore, when the selected ensemble has not been appropriately received by the signal selecting and receiving portion for more than the predetermined period under the situation in which the signal selecting and receiving portion is caused to receive the selected ensemble, such a condition that another ensemble is selected to be received in place of the selected ensemble by the signal selecting and receiving portion in accordance with the indication by the control information data or that the receivable ensembles are detected one by one by the signal selecting and receiving portion and data representing the result of the detection by the signal selecting and receiving portion are stored in the memory portion, is automatically established. Then, when the receivable ensembles are detected one by one by the signal selecting and receiving portion and the data representing the result of the detection by the signal selecting and receiving portion are stored in the memory portion, for example, the control unit performs a further control operation for causing the signal selecting and receiving portion to select one of the detected receivable ensembles to receive with reference to the data stored in the memory portion, so that a condition in which one of the detected receivable ensembles is selected to be received by the signal selecting and receiving portion is established.

Consequently, with the apparatus for receiving broadcasting signals according to the present invention, when a selected ensemble having been received falls into a condition unable to be received, a new ensemble, from which program information data corresponding to the program information data obtained based on the selected ensemble are successively obtained and thereby audio program data or service program data corresponding to the audio program data or service program data reproduced previously are successively reproduced, can be easily received without an operation for changing a receiving frequency repeatedly by a user of the apparatus.

There is also provided, according to the present invention, a method of receiving broadcasting signals, which comprises the steps of selecting one of ensembles to receive by a signal selecting and receiving portion so as to obtain program information data and control information data based on the selected ensemble, detecting a condition in which the selected ensemble has not been appropriately received by the signal selecting and receiving portion for more than a predetermined period under a situation in which a receiving frequency has been set in the signal selecting and receiving portion for receiving the selected ensemble, and performing a control operation, when the condition is detected, in such a manner as to cause the signal selecting and receiving portion to select another ensemble to receive in accordance with indication by the control information data in the case where the control information data obtained based on the selected ensemble indicate the existence of some other ensemble which is to be received in place of the selected ensemble and to cause the signal selecting and receiving portion to change the receiving frequency successively within a predetermined frequency range so as to detect receivable ensembles one by one and to store in a memory portion control information data obtained based on each receivable ensemble detected by the signal selecting and receiving portion in the case where the control information data obtained based on the selected ensemble do not indicate the existence of any ensemble which is to be received in place of the selected ensemble.

In the method of receiving broadcasting signals thus constituted in accordance with the present invention, when the selected ensemble has not been appropriately received by the signal selecting and receiving portion for more than the predetermined period under the situation in which the receiving frequency has been set in the signal selecting and receiving portion for receiving the selected ensemble, such a condition that another ensemble is selected to be received in place of the selected ensemble by the signal selecting and receiving portion in accordance with the indication by the control information data or that the receivable ensembles are detected one by one by the signal selecting and receiving portion and the control information data obtained based on each receivable ensemble detected by the signal selecting and receiving portion are stored in the memory portion, is automatically established. Then, when the receivable ensembles are detected one by one by the signal selecting and receiving portion and the control information data obtained based on each receivable ensemble detected by the signal selecting and receiving portion are stored in the memory portion, for example, a further control operation is performed for causing the signal selecting and receiving portion to select one of the detected receivable ensembles to receive with reference to the data stored in the memory portion, so that a condition in which one of the detected receivable ensembles is selected to be received by the signal selecting and receiving portion is established.

Consequently, with the method of receiving broadcasting signals according to the present invention, when a selected ensemble having been received falls into a condition unable to be received, a new ensemble, from which program information data corresponding to the program information data obtained based on the selected ensemble are successively obtained and thereby audio program data or service program data corresponding to the audio program data or service program data reproduced previously are successively reproduced, can be easily received without an operation for changing a receiving frequency repeatedly.

The above, and other objects, features and advantages of the present invention will be become apparent from the following detailed description taken in conjunction with the accompanying drawings.

### BRIEF DESCRIPTION OF THE DRAWINGS

FIG. 1 is a schematic block diagram showing an embodiment of apparatus for receiving broadcasting signals according to the present invention, in which an embodiment of method of receiving broadcasting signals according to the present invention is carried out;

FIGS. 2A to 2E are illustrations showing data formats used for explaining a digital audio broadcasting signal received by the embodiment shown in FIG. 1;

FIG. 3 is an illustration showing a data format used for explaining audio program data obtained by the embodiment shown in FIG. 1; and

FIG. 4 is a flow chart showing an example of an operational program for microcomputer used in a control unit employed in the embodiment shown in FIG. 1.

### DESCRIPTION OF THE PREFERRED EMBODIMENT

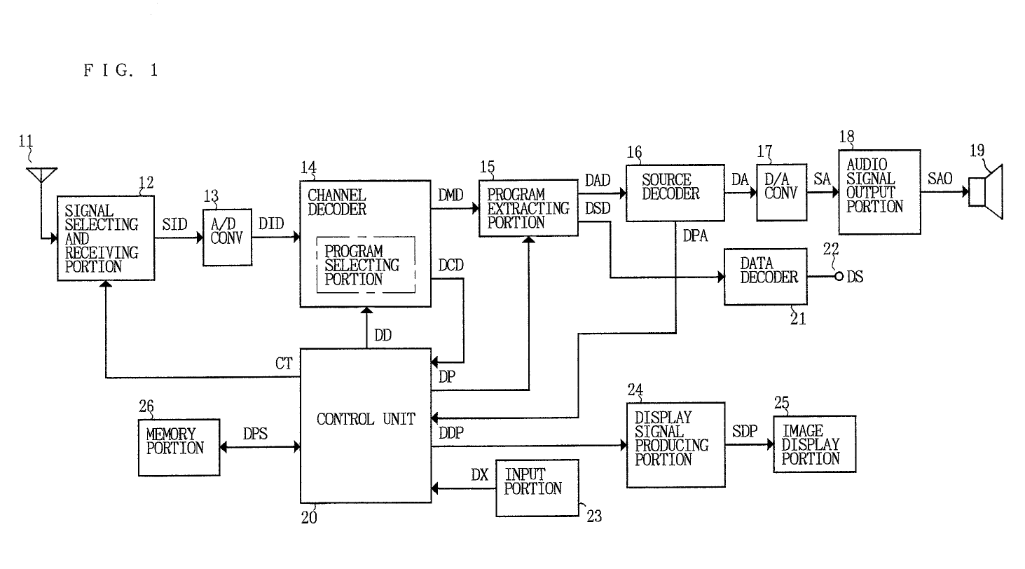

FIG. 1 shows schematically an embodiment of apparatus for receiving broadcasting signals according to the present invention, in which an embodiment of method of receiving broadcasting signals according to the present invention is carried out. This embodiment may be installed in a vehicle to move with the vehicle.

Referring to FIG. 1, in the embodiment, a specific one of ensembles, namely, digital audio broadcasting signals transmitted from a broadcasting station and having reached to a receiving antenna 11, which has a transmission frequency coincident with a receiving frequency set in a signal selecting and receiving portion 12 is selected to be received by the signal selecting and receiving portion 12.

The ensemble selected by the signal selecting and receiving portion 12 is a modulated wave signal obtained by modulating a carrier wave signal with digital data in accordance with the Orthogonal Frequency Division Multiplexing (OFDM) system and the digital data is composed of a series of frame units, each of which is called a transmission frame.

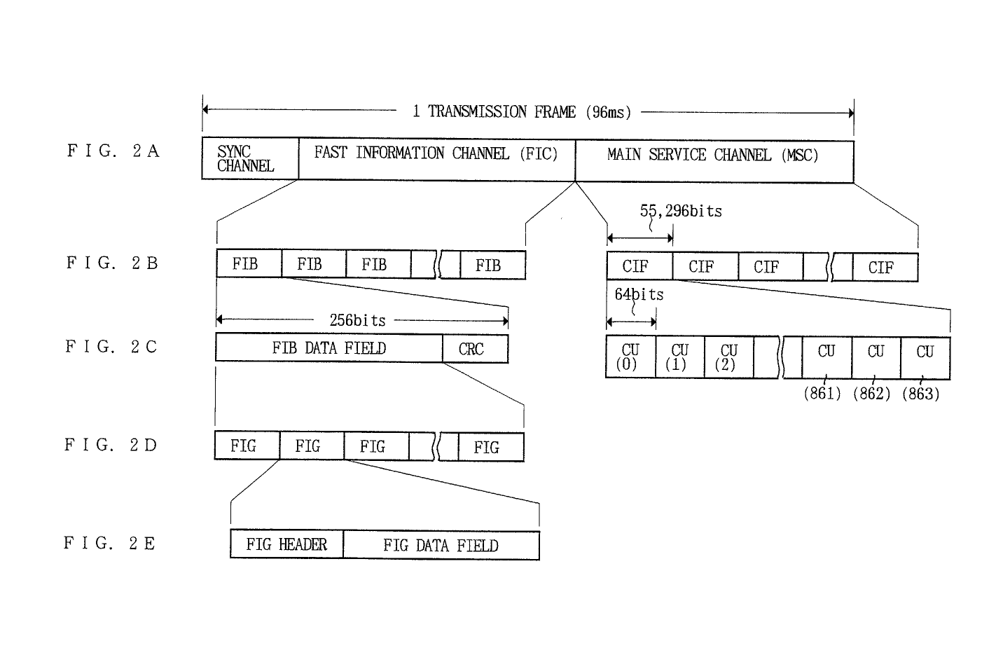

The transmission frame has a time duration of, for example, 96 ms and contains three portions of a synchronous channel, a fast information channel (FIC) and a main service channel (MSC), as shown in FIG. 2A. The MSC is composed of a series of common interleaved frames (CIFs), as shown in FIG. 2B. Each of the CIFs corresponds to 55,296 bits and is composed of a series of 864 capacity units (CUs) identified with numbers (0) to (863), respectively, as shown in FIG. 2C. Each of the capacity units forms unit data corresponding to 64 bits. The MSC thus constituted transmits audio information and service information.

The FIC is composed of series of first information blocks (FIBs), as shown in FIG. 2B. Each of the FIBs corresponds to 256 bits and contains a couple of portions of a FIB data field and an error checking word CRC (Cyclic Redundancy Check), as shown in FIG. 2C. The FIB data field is composed of a series of first information groups (FIGs), as shown in FIG. 2D. Each of the FIGs contains a couple of portions of an FIG header and an FIG data field, as shown in FIG. 2E. The FIC thus formed transmits control information, such as multiplex configuration information (MCI) and other information.

In the case where the ensemble selected to be received carries, in addition to program information data representing the audio information and the service information, service link information which represents one or more ensembles each carrying program information data corresponding to the program information data carried by the ensemble selected to be received, one or more FIGs are used for transmitting the service link information.

The receiving frequency in the signal selecting and receiving portion 12 is set in accordance with a reception control signal CT supplied from a control unit 20 constituting an operation control portion. In the signal selecting and receiving portion 12, the ensemble selected to be received is subjected to amplifying processing and frequency-converting processing to produce an intermediate frequency (IF) signal SID. The IF signal SID is supplied to an analog to digital (A/D) convertor 13. A digital IF signal DID corresponding to the IF signal SID is obtained from the A/D convertor 13 to be supplied to a channel decoder 14.

The channel decoder 14 contains a program selecting portion which is operative to select and extract a specific one of various kinds of program information data transmitted by the ensemble selected to be deceived by the signal selecting and receiving portion 12. In the channel decoder 14, the digital IF signal DID is subjected to quadrature demodulation processing, transformation from a time domain signal to a frequency demean signal and so on to produce control information data which represent control information including MCI and transmitted through the FIC and composite data which are composed of audio program data and service program data representing respectively audio information and service information transmitted through the MSC. When the FIC contains one or more FIGs used for transmitting service link information, the control information data which represent the control information including the MCI and transmitted through the FIC have a portion representing the service link information.

Further, in the channel decoder 14, the audio program data and service program data are subjected respectively to program selecting processings in the program selecting portion, the audio program data and service program data obtained from the program selecting portion to represent selected program information are subjected respectively to time de-interleaving arrangements, and the audio program data and service program data subjected to the time de-interleaving arrangements and the control information data are subjected respectively to error correction processings, so that control information data DCD subjected to the error correction processing are obtained from the channel decoder 14 to be supplied to the control unit 20 and program information data DMD which are composed of the audio program data and service program data subjected respectively to the error correction processings are also obtained from the channel decoder 14 to be supplied to a program extracting portion 15.

In the program extracting portion 15, audio program data DAD or service program data DSD are extracted from the program information data DMD. The audio program data DAD derived from the program extracting portion 15 are supplied to a source decoder 16. In the source decoder 16, the audio program data DAD are subjected to a high efficiency decoding by which data suppressed in accordance with a high efficiency coding are expanded to produce decoded audio data DA which form a digital audio signal representing the selected program information. Further, program associated data DPA which are contained in the audio program data DAD are obtained from the source decoder 16 to be supplied to the control unit 20.

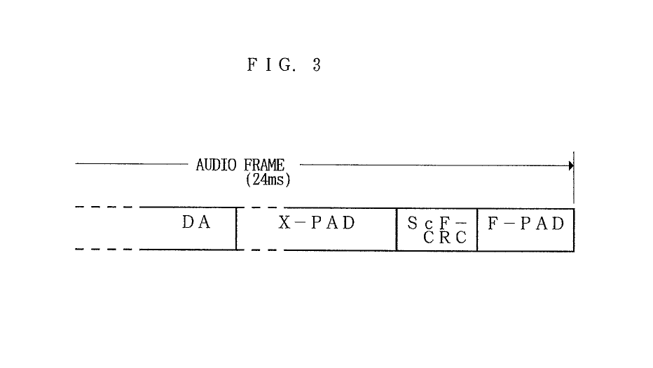

The program associated data DPA contained in the audio program data DAD contain, for example, variable program associated data X-PAD successive to audio data DA in an audio frame constituted by the audio program data DAD and fixed program associated data F-PAD, as shown in FIG. 3. ScF-CRC in the audio frame shown in FIG. 3 is an error detecting word for scale factor data (not shown in FIG. 3) contained in the audio frame.

Such program associated data DPA obtained from the source decoder 16 represent various information relative to contents of the program information represented by the audio data DA which are accompanied with the program associated data DPA. For example, in the case where the program information represented by the audio data DA is information representing music, the program associated data DPA represent in the form of character information the name of a composer of the music, the name of the music, the title of a recording medium on which the music is recorded and so on.

The decoded audio data DA forming the digital audio signal and obtained from the source decoder 16 are supplied to a digital to analog (D/A) convertor 17 to be converted to an analog sound signal forming a reproduced audio signal SA corresponding to the decoded audio data DA. The reproduced audio signal SA is derived from the D/A convertor 17 to be supplied through an audio signal output portion 18 to a speaker 19 as an audio output signal SAO. Thereby, reproduced sound based on the decoded audio data DA derived from the source decoder 16 is obtained from the speaker 19. The D/A convertor 17, the audio signal output portion 18 and the speaker 19 in the aggregate constitute a sound reproducing portion for reproducing the sound based on the decoded audio data DA forming the digital audio signal and obtained from the source decoder 16.

The service program data DSD derived from the program extracting portion 15 are supplied to a data decoder 21. In the data decoder 21, the service program data DSD are subjected to decoding processing to produce reproduced service data DS based on the service program data DSD. The reproduced service data DS are derived from the data decoder 21 to an output terminal 22.

The control unit 20 is operative to produce control data DD and DP based on the control information data DCD from the channel decoder 14, command data DX supplied from an input portion 23 in response to external manual operations thereto so on and to supply the channel decoder 14 and the program extracting portion 15 with the control data DD and DP, respectively, for controlling the operation of each of the channel decoder 14 and the program extracting portion 15. The control unit 20 is operative also to produce the reception control signal CT aforementioned based on the control information data DCD or the command data DX supplied from the input portion 23.

The control operations performed in response to the command data DX supplied from the input portion 23, the control information data DCD and so on in the control unit 20 are displayed on an image display portion 25 to which an image display signal SDP produced based on displaying data DDP which are supplied from the control unit 20 in a display signal producing portion 24 is supplied. The display signal producing portion 24 and the image display portion 25 in the aggregate constitute a displaying portion connected to the control unit 20.

In addition to the above, a memory portion 26 constituted with, for example, a random access memory (RAM) connected to the control unit 20. Various data including a portion of the control information data DCD supplied to the control unit 20, which represents the service link information, a selected portion of the program associated date DPA, other data obtained in the control unit 20 and so on are stored in the memory portion 26 as preservation data DPS and the preservation data DPS stored in the memory portion 26 are read out from the memory portion 26 to the control unit 20.

With the structure described above, when the ensemble selected to be received falls into a condition unable to be appropriately received by the signal selecting and receiving portion 12 under a situation in which the signal selecting and receiving portion 12 is caused to receive the selected ensemble, such an undesirable condition that the ensemble selected to be received is not appropriately received by the signal selecting and receiving portion 12 is detected by the control unit 20.

On that occasion, the control unit 20 is operative to detect the undesirable condition, for example, on the strength of the state of the control information data DCD supplied from the channel decoder 14 or the state of the program associated data DPA supplied from the source decoder 16. Then, when the undesirable condition is detected, the control unit 20 is operative to decide whether the detected undesirable condition continues for more than a predetermined period or not, in order to eliminate a temporary undesirable condition in which the ensemble selected to be received falls into the condition unable to be appropriately received by the signal selecting and receiving portion 12 for the reason that, for example, the vehicle in which the embodiment shown in FIG. 1 is installed runs into a tunnel or the like.

If the undesirable condition does not continue for more than the predetermined period but turns to a desirable condition in which the ensemble selected to be received is appropriately received by the signal selecting and receiving portion 12, the control unit 20 makes a decision that the temporary undesirable condition has occurred and does not perform any particular control operation.

To the contrary, if the undesirable condition continues for more than the predetermined period, the control unit 20 makes a decision that the ensemble selected to be received has continuously fallen into the condition unable to be appropriately received by the signal selecting and receiving portion 12 without recovering and is operative to decide whether the portion of the control information data DCD which represents the service link information is stored in the memory portion 26 or not. The service link information represents one or more rensembles, each of which carries program information data corresponding to the program information data carried by the ensemble which has been unable to be received by the signal selecting and receiving portion 12.

When the portion of the control information data DCD which represents the service link information is stored in the memory portion 26, the control unit 20 is operative to read that portion of the control information data DCD from the memory portion 26 and to search the service link information represented by the portion of the control information data DCD read from the memory portion 26 for finding out an ensemble which carries program information data corresponding to the program information data DMD having been selected by the program selecting portion contained in the channel decoder 14. When the ensemble which carries the program information data corresponding to the program information data DMD having been selected by the program selecting portion is found out, the control information data DCD indicates the existence of the ensemble which is to be received in place of the ensemble having been unable to be received by the signal selecting and receiving portion 12.

Accordingly, the control unit 20 is operative to supply the signal selecting and receiving portion 12 with the reception control signal CT for changing the receiving frequency in the signal selecting and receiving portion 12 to select and receive the ensemble found out based on the service link information and to cause the signal selecting and receiving portion 12 to select and deceive the ensemble represented by the service link information. As a result, such a condition that new program information data which correspond to the program information data DMD having been selected by the program selecting portion contained in the channel decoder 14 are newly selected by the program selecting portion and derived from the channel decoder 14 as the program information data DMD is automatically established.

On the other hand, when the portion of the control information data DCD which represents the service link information is not stored in the memory portion 26 or the ensemble which carries the program information data corresponding to the program information data DMD having been selected by the program selecting portion is not found out based on the service link information represented by the portion of the control information data DCD, the control information data DCD does not indicate the existence of the ensemble which is to be received in place of the ensemble having been unable to be received by the signal selecting and receiving portion 12.

In such a case, the control unit 20 is operative to supply the signal selecting and receiving portion 12 with the reception control signal CT for changing the receiving frequency in the signal selecting and receiving portion 12 successively within a predetermined frequency range and to cause the signal selecting and receiving portion 12 to perform a seeking operation for detecting receivable ensembles one by one. The control unit 20 is further operative to store the control information data obtained based on the detected receivable ensemble from the channel decoder 14 in the memory portion 26 as the preservation data DPS at every detection of the receivable ensembles. In such a case, the control information data DCD stored in the memory portion 26 as the preservation data DPS include at least received ensemble information data which correspond to a portion of the control information data DCD obtained based on the detected receivable ensemble, which represents the transmission frequency of the detected receivable ensemble, the program information data carried by the detected receivable ensemble and so on.

During the seeking operation by the signal selecting and receiving portion 12, the control unit 20 supplies the display signal producing portion 24 with the displaying data DDP for displaying the seeking operation. As a result, the seeking operation by the signal selecting and receiving portion 12 is displayed on the image display portion 25.

Further, when the seeking operation by the signal selecting and receiving portion 12 has been finished, the control unit 20 produces the displaying data DDP for displaying all program information data which can be obtained from the channel decoder 14 based on the received ensemble information data stored in the memory portion 26 and supplies the display signal producing portion 24 with that displaying data DDP. As a result, all program information data which can be obtained from the channel decoder 14 are displayed on the image display portion 25.

Then, the control unit 20 waits for the command data DX supplied from the input portion 23 in the form of program selection command data for designating one of various kinds of program information data which are able to be obtained in the channel decoder 14. When the command data DX is actually supplied in the form of program selection command data, the control unit 20 is operative to specify the ensemble carrying the program information data designated by the command data DX on the strength of the received ensemble information data stored in the memory portion 26. The control unit 20 is operative further to supply the signal selecting and receiving portion 12 with the reception control signal CT for changing the receiving frequency in the signal selecting and receiving portion 12 to select and receive the specified ensemble and to cause the signal selecting and receiving portion 12 to select and receive actually the specified ensemble. This results in that the program information data which are designated by the command data DX supplied in the form of program selection command data are obtained in the channel decoder 14 and derived from the channel decoder 14 as the program information data DMD.

After that, the control unit 20 supplies the display signal producing portion 24 with the displaying data DDP for displaying the reception of the ensemble by the signal selecting and receiving portion 12. As a result, the reception of the ensemble by the signal selecting and receiving portion 12 is displayed on the image display portion 25.

As described above, when the selected ensemble has not been appropriately received by the signal selecting and receiving portion 12 for more than the predetermined period, the control unit 20 to which the control information data DCD obtained from the first decoder are supplied performs the control operation as follows. If the control information data DCD obtained based on the selected ensemble indicate the existence of some other ensemble which is to be received in place of the selected ensemble, the control unit 20 controls the signal selecting and receiving portion 12 to select another ensemble to receive in accordance with the indication by the control information data DCD. To the contrary, if the control information data DCD obtained based on the selected ensemble do not indicate the existence of some other ensemble which is to be received in place of the selected ensemble, the control unit 20 controls the signal selecting and receiving portion 12 to change the receiving frequency successively within the predetermined frequency range so as to detect the receivable ensembles one by one and stores in the memory the control information data DCD obtained from the first decoder based on each receivable ensemble detected by the signal selecting and receiving portion 12.

Therefore, when the selected ensemble has not been appropriately received by the signal selecting and receiving portion 12 for more than the predetermined period under the situation in which the signal selecting and receiving portion 12 is caused to receive the selected ensemble, such a condition that another ensemble is selected to be received in place of the selected ensemble by the signal selecting and receiving portion 12 or that the receivable ensembles are detected one by one by the signal selecting and receiving portion 12 and data representing the result of the detection by the signal selecting and receiving portion 12 are stored in the memory portion 26 and the signal selecting and receiving portion 12 is caused to select and receive one of the detected receivable ensembles with reference to the data stored in the memory portion 26 so that one of the detected receivable ensembles is selected to be received by the signal selecting and receiving portion 12, is automatically established. Consequently, with the embodiment shown in FIG. 1, when a selected ensemble having been received falls into a condition unable to be received, another ensemble, from which program information data corresponding to the program information data DMD obtained based on the selected ensemble are successively obtained, can be easily received without any manual operation by a user of the embodiment for changing repeatedly the receiving frequency set in the signal selecting and receiving portion 12.

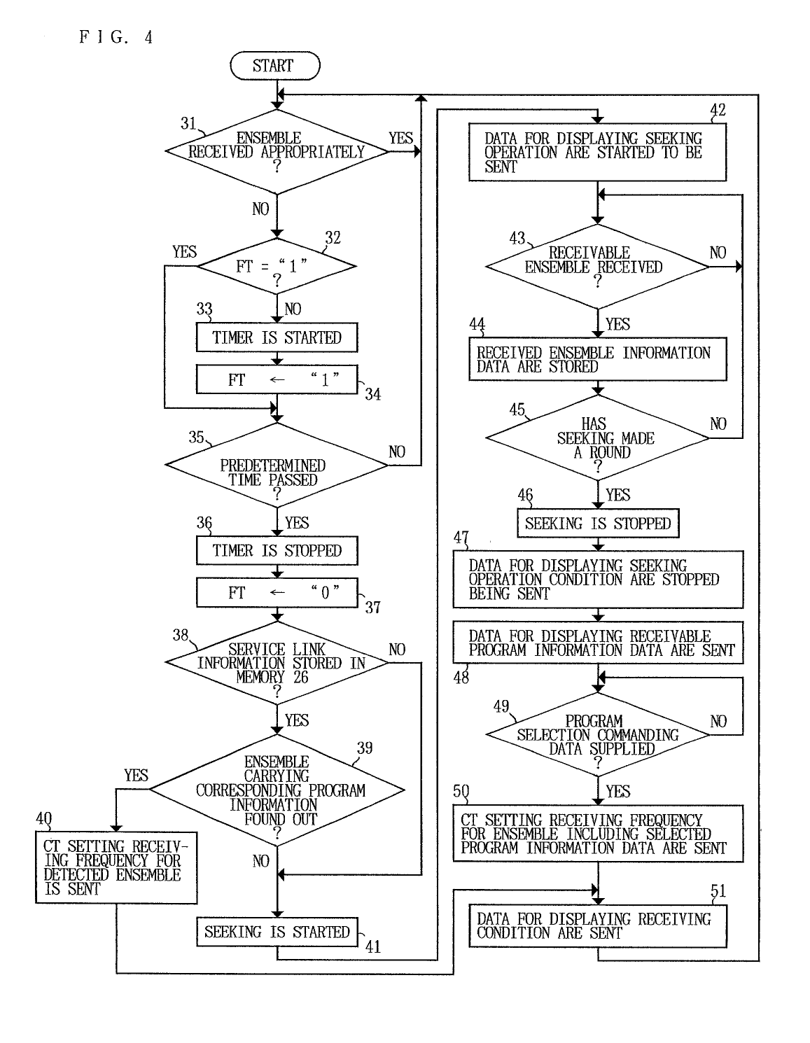

FIG. 4 shows a flow chart representing an example of a control program which the control unit 20 carries out when a selected ensemble has not been appropriately received by the signal selecting and receiving portion 12 under the situation in which the signal selecting and receiving portion 12 is caused to receive the selected ensemble.

According to the flow chart shown in FIG. 4, the program starts in a situation in which the signal selecting and receiving portion 12 is caused to receive a selected ensemble. Then, in step 31, it is checked whether the selected ensemble is appropriately received by the signal selecting and receiving portion 12 or not. If the selected ensemble is appropriately received by the signal selecting and receiving portion 12, the check in the step 31 is repeated. If the selected ensemble is not appropriately received by the signal selecting and receiving portion 12, it is checked whether a timer flag FT is “1” or not in step 32.

If it is clarified in the step 32 that the timer flag FT is not “1” but “0”, a timer contained in the control unit 20 is caused to start its operation in step 33 and the timer flag FT is set to be “1” in step 34. Then, the process is advanced to step 35.

If it is clarified in the step 32 that the timer flag FT is “1”, the process is advanced directly to the step 35 from the step 32.

In the step 35, it is checked whether a predetermined time has passed after the start of the timer or not, that is, the selected ensemble has not been appropriately received by the signal selecting and receiving portion 12 for more than a predetermined period or not. If the predetermined time has not passed yet after the start of the timer, the process returns to the step 31. If the predetermined time has passed after the start of the timer, the timer is caused to stop its operation in step 36 and the timer flag FT is set to be “0” in step 37. Then, the process is advanced to step 38.

In the step 38, it is checked that the portion of the control information data DCD which represents the service link information is stored in the memory portion 26 or not. If the portion of the control information data DCD which represents the service link information is stored in the memory portion 26, the portion of the control information data DCD is read from the memory portion 26 and it is checked whether one or more ensembles each carrying program information data which correspond to the program information data DMD having been selected by the program selecting portion contained in the channel decoder 14 are found out by searching the service link information represented by the portion of the control information data DCD read from the memory portion 26 or not, in step 39.

If it is clarified in the step 39 that one or more ensembles each carrying program information data which correspond to the program information data DMD having been selected by the program selecting portion contained in the channel decoder 14 are found out, the reception control signal CT for changing the receiving frequency in the signal selecting and receiving portion 12 to select and receive the ensemble found out based on the service link information is sent to the signal selecting and receiving portion 12 in step 40 and then the process is advanced directly to step 51 from the step 40.

If it is clarified in the step 39 that any ensemble carrying program information data which correspond to the program information data DMD having been selected by the program selecting portion contained in the channel decoder 14 are not found out, the process is advanced to step 41. Further, if it is clarified in the step 38 that the portion of the control information data DCD which represents the service link information is not stored in the memory portion 26, the process is also advanced directly to the step 41 from the step 38.

In the step 41, the reception control signal CT for changing the receiving frequency in the signal selecting and receiving portion 12 successively within the predetermined frequency range is sent to the signal selecting and receiving portion 12 and thereby the signal selecting and receiving portion 12 is caused to start the seeking operation for detecting the receivable ensembles one by one. Then, in step 42, the displaying data DDP for displaying the seeking operation by the signal selecting and receiving portion 12 are started to be sent to the display signal producing portion 24, and the process is advanced to step 43.

In the step 43, it is checked whether the receivable ensemble is detected through the seeking operation by the signal selecting and receiving portion 12 or not. If the receivable ensemble is not detected, the check in the step 43 is repeated. If the receivable ensemble is detected, the portion of the control information data DCD obtained based on the detected receivable ensemble from the channel decoder 14, which represents the transmission frequency of the detected receivable ensemble, the program information data carried by the detected receivable ensemble and so on and constitutes the received ensemble information data, is stored in the memory portion 26 as the preservation data DPS in step 44.

Next, it is checked in step 45 whether the seeking operation by the signal selecting and receiving portion 12 has made a round or not. If the seeking operation has not made a round yet, the process returns to the step 43. If the seeking operation has made a round, the signal selecting and receiving portion 12 is caused to stop the seeking operation in step 46 and the displaying data DDP for displaying the seeking operation by the signal selecting and receiving portion 12 are stopped being sent to the display signal producing portion 24 in step 47. Then, the process is advanced to step 48.

In the step 48, the displaying data DDP for displaying all program information data which can be obtained from the channel decoder 14 are produced based on the received ensemble information data stored in the memory portion 26 and then sent to the display signal producing portion 24.

After that, it is checked in step 49 whether the command data DX is supplied from the input portion 23 in the form of program selection command data for designating one of various kinds of program information data which are able to be obtained in the channel decoder 14 or not. If the command data DX is not supplied in the form of program selection command data, the check in the step 49 is repeated. If the command data DX is supplied in the form of program selection command data, the ensemble carrying the program information data designated by the command data DX is specified on the strength of the received ensemble information data stored in the memory portion 26 and the reception control signal CT for changing the receiving frequency in the signal selecting and receiving portion 12 to select and receive the specified ensemble is sent to the signal selecting and receiving portion 12, in 50. Then, the process is advanced to the step 51. In the step 51, the displaying data DDP for displaying the reception of the ensemble by the signal selecting and receiving portion 12 are sent to the display signal producing portion 24, and the process urns to the step 31.

What is claimed is:

1. An apparatus for receiving broadcasting signals comprising:
a signal selecting and receiving portion for selecting one of digital audio broadcasting signals to receive,
a first decoding portion for obtaining program information data and control information data based on the selected digital audio broadcasting signal received by said signal selecting and receiving portion,
a program extracting portion for extracting audio program data from the program information data obtained from said first decoding portion,
a second decoding portion for decoding the audio program data obtained from said program extracting portion to obtain a digital audio signal,
a sound reproducing portion for reproducing sound based on the digital audio signal obtained from said second decoding portion, and
an operation control portion to which the control information data obtained from said first decoding portion are supplied,
wherein said operation control portion is operative to detect a condition in which the selected digital audio broadcasting signal has not been appropriately received by said signal selecting and receiving portion for more than a predetermined period and, when the condition is detected, to perform a control operation in such a manner as to cause said signal selecting and receiving portion to select another digital audio broadcasting signal to receive in accordance with indication by the control information data in the case where the control information data obtained based on the selected digital audio broadcasting signal indicate the existence of some other digital audio broadcasting signal which is to be received in place of the selected digital audio broadcasting signal, and to cause said signal selecting and receiving portion to change a receiving frequency successively within a predetermined frequency range so as to detect receivable digital audio broadcasting signals one by one and to store in a memory portion control information data obtained from said first decoding portion based on each receivable digital audio broadcasting signal detected by said signal selecting and receiving portion in the case where the control information data obtained based on the selected digital audio broadcasting signal do not indicate the existence of any digital audio broadcasting signal which is to be received in place of the selected digital audio broadcasting signal.

2. An apparatus for receiving broadcasting signals according to claim 1, wherein said operation control portion is operative to detect the condition in which the selected digital audio broadcasting signal has not been appropriately received by said signal selecting and receiving portion for more than the predetermined period on the strength of the state of the control information data.

3. An apparatus for receiving broadcasting signals according to claim 2, wherein said memory portion is constituted with a random access memory connected to the operation control portion.

4. An apparatus for receiving broadcasting signals according to claim 2, wherein an input portion is connected to the operation control portion and said operation control portion is operative, in response to command data supplied from said input portion, to cause the signal selecting and receiving portion to select and receive a digital audio broadcasting signal corresponding to selected one of the control information data stored in the memory portion.

5. An apparatus for receiving broadcasting signals according to claim 4, wherein a displaying portion is connected to the operation control portion and said operation control portion is operative to cause said displaying portion to display program information data which can be obtained from the first decoding portion and are represented by the control information data stored in the memory portion.

6. An apparatus for receiving broadcasting signals according to claim 5, wherein said program extracting portion is operative to extract, in addition to the audio program data, service program data from the program information data obtained from the first decoding portion and a third decoding portion is provided for decoding the service program data derived from said program extracting portion to obtain reproduced service data.

7. An apparatus for receiving broadcasting signals according to claim 4, wherein said program extracting portion is operative to extract, in addition to the audio program data, service program data from the program information data obtained from the first decoding portion and a third decoding portion is provided for decoding the service program data derived from said program extracting portion to obtain reproduced service data.

8. An apparatus for receiving broadcasting signals according to claim 2, wherein a displaying portion is connected to the operation control portion and said operation control portion is operative to cause said displaying portion to display program information data which can be obtained from the first decoding portion and are represented by the control information data stored in the memory portion.

9. An apparatus for receiving broadcasting signals according to claim 8, wherein said program extracting portion is operative to extract, in addition to the audio program data, service program data from the program information data obtained from the first decoding portion and a third decoding portion is provided for decoding the service program data derived from said program extracting portion to obtain reproduced service data.

10. An apparatus for receiving broadcasting signals according to claim 2, wherein said program extracting portion is operative to extract, in addition to the audio program data, service program data from the program information data obtained from the first decoding portion and a third decoding portion is provided for decoding the service program data derived from said program extracting portion to obtain reproduced service data.

11. An apparatus for receiving broadcasting signals according to claim 1, wherein said memory portion is constituted with a random access memory connected to the operation control portion.

12. An apparatus for receiving broadcasting signals according to claim 1, wherein an input portion is connected to the operation control portion and said operation control portion is operative, in response to command data supplied from said input portion, to cause the signal selecting and receiving portion to select and receive a digital audio broadcasting signal corresponding to selected one of the control information data stored in the memory portion.

13. An apparatus for receiving broadcasting signals according to claim 1, wherein a displaying portion is connected to the operation control portion and said operation control portion is operative to cause said displaying portion to display program information data which can be obtained from the first decoding portion and are represented by the control information data stored in the memory portion.

14. An apparatus for receiving broadcasting signals according to claim 1, wherein said program extracting portion is operative to extract, in addition to the audio program data, service program data from the program information data obtained from the first decoding portion and a third decoding portion is provided for decoding the service program data derived from said program extracting portion to obtain reproduced service data.

15. A method of receiving broadcasting signals comprising the steps of:
selecting one of digital audio broadcasting signals to receive by a signal selecting and receiving portion so as to obtain program information data and control information data based on the selected digital audio broadcasting signal,
detecting a condition in which the selected digital audio broadcasting signal has not been appropriately received by the signal selecting and receiving portion for more than a predetermined period under a situation in which a receiving frequency has been set in the signal selecting and receiving portion for receiving the selected digital audio broadcasting signal, and
performing a control operation, when said condition is detected, in such a manner as to cause the signal selecting and receiving portion to select another digital audio broadcasting signal to receive in accordance with indication by the control information data in the case where the control information data obtained based on the selected digital audio broadcasting signal indicate the existence of some other digital audio broadcasting signal which is to be received in place of the selected digital audio broadcasting signal and to cause the signal selecting and receiving portion to change the receiving frequency successively within a predetermined frequency range so as to detect receivable digital audio broadcasting signals one by one and to store in a memory portion control information data obtained based on each receivable digital audio broadcasting signal detected by the signal selecting and receiving portion in the case where the control information data obtained based on the selected digital audio broadcasting signal do not indicate the existence of any digital audio broadcasting signal which is to be received in place of the selected digital audio broadcasting signal.

16. A method of receiving broadcasting signals according to claim 15, wherein, in said detecting step, the condition in which the selected digital audio broadcasting signal has not been appropriately received by said signal selecting and receiving portion for more than the predetermined period is detected on the strength of the state of the control information data.

17. A method of receiving broadcasting signals according to claim 15 further comprising the step of performing a further control operation to cause the signal selecting and receiving portion to select and receive a digital audio broadcasting signal corresponding to selected one of the control information data stored in the memory portion in response to command data supplied from an input portion.

18. A method of receiving broadcasting signals according to claim 15 further comprising the step of performing a further control operation to display program information data which can be obtained and are represented by the control information data stored in the memory portion.

19. A method of receiving broadcasting signals according to claim 15 further comprising the steps of extracting audio program data and service program data from the program information data and decoding the service program data to obtain reproduced service data.

20. A method of receiving broadcasting signals comprising the steps of:
selecting one of digital audio broadcasting signals to receive by a signal selecting and receiving portion so as to obtain program information data and control information data based on the selected digital audio broadcasting signal,
detecting a condition in which the selected digital audio broadcasting signal has not been appropriately received by the signal selecting and receiving portion for more than a predetermined period on the strength of the state of the control information data under a situation in which a receiving frequency has been set in the signal selecting and receiving portion for receiving the selected digital audio broadcasting signal,
performing a control operation, when said condition is detected, in such a manner as to cause the signal selecting and receiving portion to select another digital audio broadcasting signal to receive in accordance with indication by the control information data in the case where the control information data obtained based on the selected digital audio broadcasting signal indicate the existence of some other digital audio broadcasting signal which is to be received in place of the selected digital audio broadcasting signal and to cause the signal selecting and receiving portion to change the receiving frequency successively within a predetermined frequency range so as to detect receivable digital audio broadcasting signals one by one and to store in a memory portion control information data obtained based on each receivable digital audio broadcasting signal detected by the signal selecting and receiving portion in the case where the control information data obtained based on the selected digital audio broadcasting signal do not indicate the existence of any digital audio broadcasting signal which is to be received in place of the selected digital audio broadcasting signal,
causing the signal selecting and receiving portion to select and receive a digital audio broadcasting signal corresponding to selected one of the control information data stored in the memory portion in response to command data supplied from an input portion, and displaying program information data which can be obtained and are represented by the control information data stored in the memory portion.
